(19) United States
(12) Patent Application Publication
(10) Pub. No.: US 2020/0273768 A1
(43) Pub. Date: Aug. 27, 2020

(54) CRYSTALLINE CARBON HEAT SPREADING MATERIALS FOR IC DIE HOT SPOT REDUCTION

(71) Applicant: Intel Corporation, Santa Clara, CA (US)

(72) Inventors: Omkar Karhade, Chandler, AZ (US); Nitin Deshpande, Chandler, AZ (US); Mitul Modi, Phoenix, AZ (US); Edvin Cetegen, Chandler, AZ (US); Aastha Uppal, Chandler, AZ (US); Debendra Mallik, Chandler, AZ (US); Sanka Ganesan, Chandler, AZ (US); Yiqun Bai, Chandler, AZ (US); Jan Krajniak, Phoenix, AZ (US); Kumar Singh, Phoenix, AZ (US)

(73) Assignee: Intel Corporation, Santa Clara, CA (US)

(21) Appl. No.: 16/287,668

(22) Filed: Feb. 27, 2019

(51) Int. Cl. H01L 23/31; H01L 23/532; H01L 23/34; H01L 23/00; H01L 21/56

(52) U.S. Cl. CPC H01L 23/3128; H01L 23/53295; H01L 23/34; H01L 21/565; H01L 24/17; H01L 24/97; H01L 21/561; H01L 24/09

(57) ABSTRACT

IC packages including a heat spreading material comprising crystalline carbon. The heat spreading material may be applied directly to an IC die surface, for example at a die prep stage, prior to an application or build-up of packaging material, so that the high thermal conductivity may best mitigate any hot spots that develop at the IC die surface during operation. The heat spreading material may be applied to surface of the IC die.

### BACKGROUND

In electronics manufacturing, integrated circuit (IC) packaging is a stage of semiconductor device fabrication, in which an IC that has been fabricated on a die (or chip) comprising a semiconducting material is encapsulated in a “package” that can protect the IC from physical damage and support electrical contacts that connect the IC to a host circuit board or another system component. In the IC industry, the process of fabricating a package is often referred to as packaging.

The power density on ever-shrinking integrated circuits continues to increase. Many new technologies, such as 5G wireless technology, will further exacerbate thermal management because of higher frequency operation and higher up-time. This problem is particularly challenging with the extremely small IC die (e.g., 1-3 mm die edge length) that are often employed in RF applications. Within these small IC die there may be highly localized power generation (e.g., within a signal amplifier circuit or RF filtering circuit) where the power density is very high, which can lead to localized temperatures well above typical junction temperature targets.

For some small-die package architectures, such as a flip-chip chip scale package (FC-CSP), heat spreading over a back (top) side of an IC die is limited. For example, a mold material that might encapsulate the package typically has a thermal conductivity of only around 2.5 W/mK, or less. As such, in some exposed die mold (EDM) packages, the top side of the die may be left exposed so that system-level thermals can interface with the IC die backside more directly. However, system-level thermals need to be applied to a packaged IC during system-level assembly, which greatly limits their effective thermal conductivity. This limitation becomes worse as the IC package become smaller with external thermal solutions all the more difficult to implement.

Solder features coupling the front (bottom) IC die surface to a package substrate (or component external to the package) may facilitate heat conduction, but primarily in the z-dimension with lateral heat spreading being minimal near the IC die. This is particularly true for small IC packages that have a small die area capable of hosting only a small number of solder features. As such, junction temperatures can far exceed acceptable limits if intrinsic hot-spots are present within an IC die.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels are repeated among the figures to indicate corresponding or analogous elements. In the figures:

FIG. 1A, 1B, 1C, 1D, and 1E illustrate cross-sectional views of an IC package including a heat spreading material comprising crystalline carbon, in accordance with some embodiments;

FIG. 2A, 2B, and 2C illustrate cross-sectional views of an IC package including a heat spreading material comprising crystalline carbon, in accordance with some embodiments;

FIG. 3 illustrates a plan view of an die package including a heat spreading material comprising crystalline carbon, in accordance with some embodiments;

FIG. 4 illustrates a flow diagram of methods for forming an IC package including a heat spreading material comprising crystalline carbon, in accordance with some embodiments;

FIG. 5A and 5B illustrate selected operations in processing an IC die and IC package to include a heat spreading material comprising crystalline carbon, in accordance with some embodiments;

FIG. 6 is a functional block diagram of an electronic computing device, in accordance with some embodiments; and

FIG. 7 illustrates a mobile computing platform and a data server machine employing an IC assembly including an IC package that has a heat spreading material comprising crystalline carbon, in accordance with some embodiments.

### DETAILED DESCRIPTION OF EXEMPLARY EMBODIMENTS

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example in the context of materials, one material or material disposed over or under another may be directly in contact or may have one or more intervening materials. Moreover, one material disposed between two materials or materials may be directly in contact with the two layers or may have one or more intervening layers. In contrast, a first material or material “on” a second material or material is in direct contact with that second material/material. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Described herein are examples of IC packages including a heat spreading material comprising crystalline carbon. The heat spreading material comprising crystalline carbon may have a high thermal conductivity. The heat spreading material may be applied directly to an IC die surface, for example at a die prep stage, prior to an application or build-up of packaging material, so that the high thermal conductivity may best mitigate any hot spots that develop at the IC die surface during device operation. In some advantageous embodiments described further below, the heat spreading material is applied to at least a sidewall of the IC die, which the inventors have found, can significantly reduce hot spot formation, particularly for ultra small form factors where the hot spot-to-die edge thermal resistance can be similar to that in z-direction. Heat spreading at the die edge surface can be made much more efficient through an application of a material comprising crystalline carbon prior to subsequent application of another dielectric material having relatively low thermal conductivity, such those typically applied during an overmold packaging process, and/or during a fan-out process. In some examples, the heat spreading material may be applied to an IC die surface by deposition of a thin coating (e.g., on the order of hundreds of nanometers to a few micrometers in thickness), or through application of a preform, which may be tens of micrometers in thickness, for example.

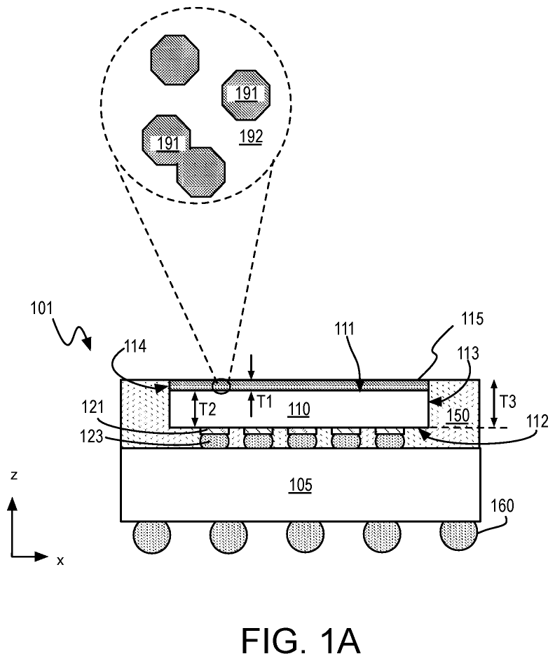

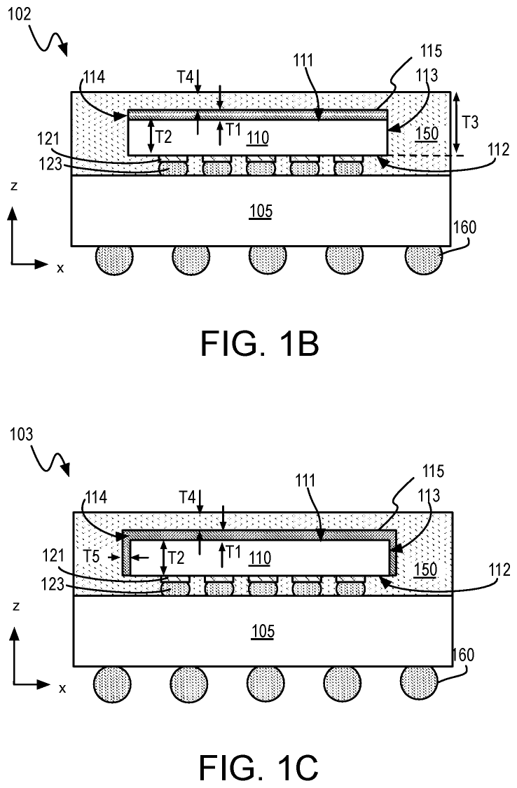

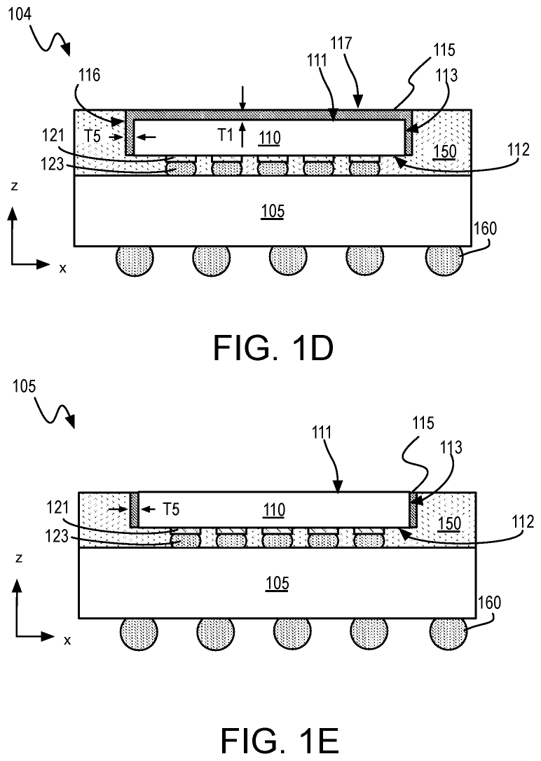

A heat spreading material in accordance with some embodiments is advantageously proximal to a surface of an IC die, and in some exemplary embodiments, is in direct contact with one or more surfaces of an IC die. FIG. 1A illustrates a cross-sectional view of an IC package 101 that includes a heat spreading material 115 proximal to one or more surfaces of IC die 110, in accordance with some embodiments. In this example heat spreading material 115 is over a top (back) side of IC die 110. In some such embodiments, heat spreading material 115 is in direct contact with a IC die back side surface 111 where heat spreading material 115 is to enhance the spread of heat over this surface (e.g., reduce thermal gradients on surface 111). Back side surface 111 may comprise a crystalline semiconductor, such as silicon, or an alloy thereof (e.g., SiGe), germanium, a III-V semiconductor alloy, or the like. One or more IC dielectric thin films (SiO, SiN, SiON, etc.) deposited following a wafer thinning process may also be present on back side surface 111.

IC die 110 may include one or more integrated circuits. In some embodiments, IC die 110 includes power management circuitry (a PMIC), radio frequency communication circuitry (RFIC), microprocessor circuitry (e.g., application processors, central processors, graphics processors), or memory circuitry (e.g., DRAM, MRAM, RRAM, etc.). In some further embodiments, IC die 110 includes System on a Chip (SoC) circuitry that may further integrate two or more of the above circuitries. Although the illustrated CSP example shows only one IC die 110, which is typical for small form factor packaging embodiments, it is noted that embodiments of the invention may also be applicable to multi-die packages.

Heat spreading material 115 has a composition including crystalline carbon. Heat spreading material 115 has a relatively high thermal conductivity (e.g., exceeding at least 100 W/mK when in a bulk state). In some advantageous embodiments, the thermal conductivity exceeds 500 W/mK, and may even exceed 1000 W/mk. In some embodiments, heat spreading material 115 is of a composition that has isotropic thermal conductivity. In other embodiments, heat spreading material 115 is of a composition that has anisotropic thermal conductivity, for example having a higher thermal conductivity in the x(y) dimension(s) than in the z-dimension. In some embodiments, heat spreading material 115 comprise predominantly crystalline carbon, which may be in the form of graphene, for example. Graphene has been found to have a thermal conductivity of up to 3000 W/mK. For embodiments where heat spreading material 115 is substantially pure graphene, a very high thermal conductivity may be achieved. For embodiments where heat spreading material 115 instead comprises crystalline carbon in other forms (e.g., in the form of graphite), or comprises a composite with graphene crystals as a filler (e.g., flakes, etc.) within a matrix material, thermal conductivity of heat spreading material 115 may be somewhat lower (e.g., 500-1500 W/mK).

The crystalline carbon of heat spreading material 115 may be in any form, such as a stack of 2D sheets oriented to have a dominant orientation (i.e., texture) that is either parallel to the x(y) axis in FIG. 1A, or parallel to the z-axis. FIG. 1A includes an expanded view of an exemplary heat spreading material 115 that further illustrates carbon crystals 191 within a matrix material 192. Carbon crystals 191 may be substantially pure carbon. Crystals 191 may have nanostructure (e.g., nanotubes). Matrix material 192 may be any material known to be both compatible with carbon crystals 191 and suitable for IC die packaging applications. Matrix material 192 may be a dielectric, and for some such embodiments, heat spreading material 115 as a whole is also a dielectric. Matrix material 192 may also comprise carbon in other than a crystalline form (e.g., organic compounds, etc.). In some specific embodiments, matrix material 192 comprises a thermoset resin (epoxy), or a silicone-based polymer (i.e., polysiloxanes including predominantly silicon, oxygen, and carbon)

Heat spreading material 115 has a material thickness T1 as measured in a direction substantially normal to IC die surface 111. Thickness T1 may vary as a function of the technique employed to apply heat spreading material 115 over IC die surface 111, and/or as a function of the thermal conductivity of the heat spreading material 115. The greater the thermal conductivity of the material, the better the heat spreading for a given material thickness T1. For embodiments where heat spreading material 115 is nearly pure graphene, material thickness T1 may be as little as a few hundred nanometers (e.g., 200-500 nm). Material thickness T1 may generally be less than about 3 μm where a chemical deposition or wet coating process (e.g., spray, etc.) is employed to apply heat spreading material 115 to IC die surface 111. In other embodiments, material thicknesses T1 is at least 10 μm where a molding process or dry film lamination process is employed to apply heat spreading material 115 to IC die surface 111. In some of these embodiments, thickness T1 is 50-200 μm. For exemplary embodiments, IC die thickness T2 is 100-250 μm, with heat spreading material thickness T1 20%-100% of IC die thickness T2.

In the illustrated example, IC package 101 is a FC-CSP in which a front (bottom) side IC die surface 112 has metallization features 121. Front-side metallization features 121 are coupled through solder features 123 to an underlying interposer, substrate or package material 105. Metallization features 121 may be a top interconnect level of IC die 110, for example, and a single feature may comprise a pad, posts, pillar, or other metal structure. Solder features 123 may be solder bumps or microbumps, for example. Package material 105 may further comprise one or more metallized redistribution or fan out layers 106 that further couple electrical metallization features 121 to package interconnects that are suitable for surface mounting package 101 to a system-level component, such as a printed circuit board (not depicted). In the illustrated example, metallization 106 is coupled to solder features 160 (e.g., bumps or balls). Solder features 160 may be larger in diameter (e.g., hundreds of μm) than solder features 123 (e.g., less than 100 μm). Solder features 160 may, be solder balls, for example, while solder features 123 may be derived from a solder paste

IC die 110 is over a center portion of package material 105 while another package material 150 is over a perimeter, or edge, portion of package material 105. IC die 110 is at least partially encapsulated within package material 150, with package material 150 being adjacent to an IC die edge sidewall 113, for example as a result of package material 150 having been molded around IC die 110. Package material 150 is advantageously a dielectric. In some exemplary embodiments, package material 150 comprises a cured resin or polymer comprising epoxy and/or silicone, or any other thermoset material known to be suitable for IC die packaging applications. Package material 150 has a substantially lower thermal conductivity than that of heat spreading material 115. In some embodiments, package material 150 has a relatively low bulk thermal conductivity (e.g., less than 5 W/mK), and may, for example, have a bulk thermal conductivity in the range of 1-3 W/(mK)

As shown in FIG. 1A, package material 150 is in contact with an edge sidewall of IC die 110. Package material 150 is also in contact with an edge sidewall 114 of heat spreading material 115, which is indicative of package material 150 having been applied (e.g., molded) subsequent to the application of heat spreading material 115 to back side IC die surface 111. As further shown, package material 150 has a z-thickness T3 from a IC die front surface 112 that is substantially equal to IC die thickness T2 summed with heat spreading material thickness T1. Such an architecture is indicative of integrating heat spreading material 115 into an EDM packaging process, for example. Any system-level thermal solutions may be applied to IC package 101 with the benefit of fewer hot spots as a result of the thermal conductivity of heat spreading material 115.

FIG. 1B illustrates a cross-sectional view of an IC package 102 in accordance with some embodiments where a heat spreading material 115 is fully encapsulated within package material 150. Reference labels from IC package 101 (FIG. 1A) are repeated in IC package 102 (FIG. 1B) to indicate analogous elements, which may have any of the same attributes described above. As shown in FIG. 1B, package material 150 has a z-thickness T3 from IC die front side 112 that exceeds IC die thickness T2 summed with heat spreading material thickness T1. In the illustrated example, package material 150 has thickness T4 over heat spreading material 115. Thickness T4 may vary, but in some examples is at least 10 μm. The architecture of IC package 102 is indicative of integrating heat spreading material 115 into a packaging overmold process, for example. Although packaging material 150 has lower thermal conductivity than heat spreading material 115, IC die surface 111 may have fewer hot spots as a result of the enhanced thermal conductivity of heat spreading material 115.

In some embodiments, a heat spreading material comprising crystalline carbon is adjacent to an edge sidewall of an IC die. Having the heat spreading material next to, or otherwise proximal to a sidewall surface of an IC die may be particularly advantageous where hot spots arise near a perimeter of an IC die, which is more likely for small IC die (e.g., less than 25 mm²). A heat spreading material may be exclusively along die edge sidewalls, or may be along the sidewalls in addition to being over a top (back) side of an IC die. FIG. 1C is a cross-sectional view of an IC package 103 with heat spreading material 115 on five inactive sides of IC die 110, in accordance with some embodiments. Reference labels from IC package 102 (FIG. 1B) are repeated in IC package 103 (FIG. 1C) to indicate analogous elements, which may have any of the same attributes described above in the context of IC package 101 (FIG. 1A). As shown in FIG. 1C, heat spreading material 115 is between IC die edge sidewall 113 and package material 150. IC die edge sidewall 113 may include crystalline semiconductor (e.g., silicon, or alloy thereof, etc.) exposed during a die singulation process. In IC package 103, heat spreading material 115 is in direct contact with IC die edge sidewall 113. In other embodiments, one or more intervening materials may be between IC die edge sidewall 113 and heat spreading material 115. As further shown, package material 150 is in direct contact with heat spreading material 115. In some exemplary embodiments, heat spreading material 115 is in contact with IC die edge sidewall 113 over the entire die thickness T2, and along substantially the entire length (e.g., in y-dimension) of IC die edge sidewall 113. In addition to being in contact with IC die edge sidewall 113, heat spreading material 115 is also in contact with IC die back side surface 111, substantially as described above for IC package 102. Package material 150 fully encapsulates heat spreading material 115, again having some non-zero package material thickness T4 over heat spreading material.

The thickness of heat spreading material on an IC die sidewall may vary with implementation. When heat spreading material is on both a die edge sidewall surface and a non-sidewall surface of an IC die, the material thickness of the heat spreading material on the die edge sidewall surface may be approximately equal to, less than, or greater than, the material thickness on the non-sidewall surface. In the example shown in FIG. 1C, heat spreading material 115 is substantially conformal. Sidewall material thickness T5 is measured in a direction substantially normal to IC die sidewall surface 113. Similar to material thickness T1, material thickness T5 may also vary as a function of the technique employed to apply heat spreading material 115 over the IC die surfaces 111 and 113. Thickness T5 may also vary as a function of the thermal conductivity of heat spreading material 115. For embodiments where heat spreading material 115 is nearly pure graphene, material thickness T5 may be as little as a few hundred nanometers (e.g., 200-500 nm). Material thicknesses (T1 and/or T5) less than about 3 μm may again be indicative of application by a chemical deposition or wet coating process (e.g., spray, etc.). Such processes may also ensure heat spreading material 115 is substantially conformal with material thicknesses T1 and T5 being nearly equal, as shown in FIG. 1C. Material thicknesses (T1 and/or T5) of at least 10 μm may again be indicative of application by a molding process or dry film lamination process. In some of these embodiments, thickness T5 is 50-200 μm, which may be 20%, or more, of the IC die thickness T2. Heat spreading material 115 may be highly non-conformal as a result of such techniques, for example with material thickness T5 potentially being significantly greater than material thickness T1.

With a significant thickness of heat spreading material 115 surrounding edge sidewalls of IC die 110, heat conduction within a plane normal to IC die edge sidewall 113 may be enhanced by the high thermal conductivity of heat spreading material 115. Any hot spots near IC die edge sidewall 113 may be mitigated through heat spread along a y-z plane parallel to die edge sidewall 113, for example. Where the entire area of IC die edge sidewall 113 is in contact with heat spreading material 115, lateral heat conduction over the entire edge sidewall length or area may occur

FIG. 1D is a cross-sectional view of an IC package 104 with heat spreading material 115 again on five sides of IC die 110, in accordance with some embodiments. Reference labels from IC packages 101-103 are repeated in IC package 104 (FIG. 1C) to indicate analogous elements, which may have any of the same attributes described above in the context of IC package 101 (FIG. 1A). As shown in FIG. 1D, heat spreading material 115 is between IC die edge sidewall 113 and package material 150. Package material 150 is present adjacent to heat spreading material sidewall 116, but absent from heat spreading material top surface 117. Similar to IC package 101, the architecture of IC package 104 is indicative of an integration of heat spreading material 115 into a EDM packaging process. Similar to IC package 103 however, heat spreading material 115 is present on five sides of IC die 110. Relative to IC package 101, IC package 104 may be expected to have enhanced thermal conduction in a plane parallel to IC die sidewall 113.

In some embodiments, heat spreading material is adjacent IC die sidewalls, but absent from a top (back) surface of the IC die. Such embodiments may rely on enhanced thermal conduction along the IC die sidewall afforded by highly localized heat spreading material. FIG. 1E is a cross-sectional view of an IC package 105 with heat spreading material 115 only present along IC die sidewall 113, in accordance with some embodiments. Reference labels from IC packages 101-104 are repeated in IC package 105 (FIG. 1C) to indicate analogous elements, which may have any of the same attributes described above in the context of IC package 101 (FIG. 1A). As shown in FIG. 1E, heat spreading material 115 is between IC die edge sidewall 113 and package material 150. Package material 150 is adjacent to heat spreading material sidewall 116 while IC die top surface 111 is fully exposed. Similar to IC packages 101 and 104, the architecture of IC package 105 is indicative of an integration of heat spreading material 115 into a EDM packaging process. In this example however, the absence of heat spreading material 115 from IC die top surface 111 may be indicative of a partial removal of heat spreading material 115, for example during an etchback or package material planarization process. Nevertheless, because IC package 105 retains heat spreading material 115 along die sidewall 113, enhanced thermal conduction along the die sidewall may reduce the occurrence of thermal hot spots within IC die 110

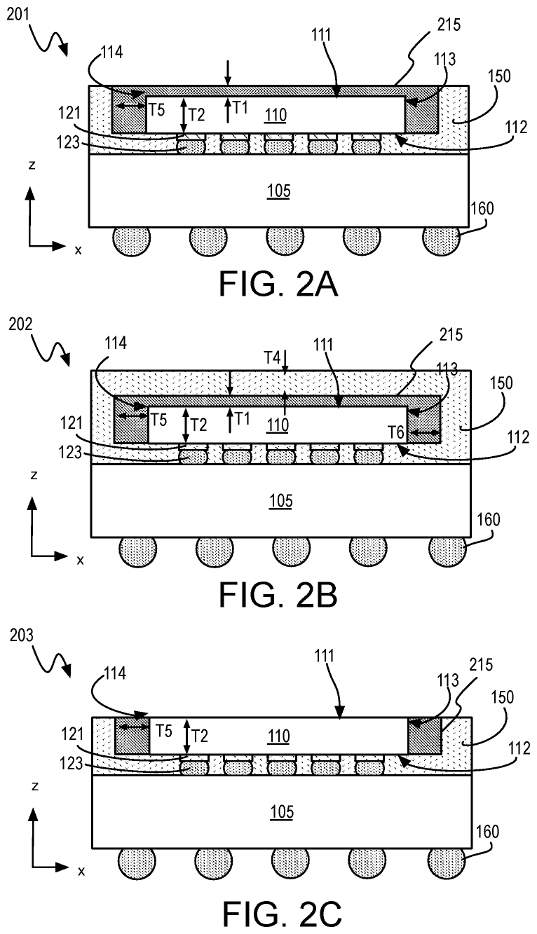

FIG. 2A-2C further illustrate some exemplary IC package architectures that include a heat spreading material having a sidewall material thickness that is comparable to the IC die thickness. As noted above, this greater sidewall material thickness may be indicative of non-conformal application of the heat spreading material. A greater heat spreading material thickness adjacent to an IC die sidewall may enhance thermal conduction along the IC die edge sidewall, particularly where heat spreading material has high thermal conductivity in the thickness dimension along with high thermal conductivity in a plane parallel with IC die edge sidewall. In FIG. 2A-2C reference labels from IC packages 101-105 are repeated in IC packages 201-203 to indicate analogous elements, which may have any of the same attributes described above in the context of IC package 101 (FIG. 1A)

FIG. 2A is a cross-sectional view of an IC package 201 that includes heat spreading material 115 in contact with IC die top surface 111 and further in contact with IC die sidewall 113, in accordance with some embodiments. IC package 201 has an architecture similar to that of IC package 104, however for IC package 203 heat spreading material 115 has a sidewall thickness T5 that is approximately equal to IC die thickness T2. The sidewall thickness T5 may be greater than top thickness T1 by a few micrometers to a few hundreds of micrometers, for example. The non-conformal thickness of heat spreading material 115 illustrated in FIG. 2A may be indicative of a package planarization process which reduced top thickness T1, for example.

FIG. 2B is a cross-sectional view of an IC package 202 that includes heat spreading material 115 in contact with IC die top surface 111 and in contact with IC die sidewall 113, in accordance with some embodiments. IC package 201 has an architecture similar to that of IC package 103, however for IC package 202 heat spreading material 115 has a sidewall thickness T5 that is approximately equal to IC die thickness T2. With package material 150 having a non-zero thickness T4, the difference in thickness T5 and T1 may be indicative of T1 being dependent upon a dry film thickness while T5 is instead a function of an IC die singulation process. Alternatively, the architecture illustrated in FIG. 2B may be indicative of a partial removal of heat spreading material 115 prior to a molding of package material 150. In some further embodiments, heat spreading material 115 may have a sidewall thickness that varies around a perimeter of an IC die. For example, in FIG. 2B, sidewall thickness T5 may differ from sidewall thickness T6 by 5-10 μm, or more. Such variation in sidewall thickness around an IC die may further indicate that the sidewall thickness of the heat spreading material is dependent upon an IC die singulation process.

FIG. 2C is a cross-sectional view of an IC package 203 with heat spreading material 115 present only along IC die sidewall 113, in accordance with some embodiments. IC package 203 has an architecture similar to that of IC package 105. However, in IC package 203 heat spreading material 115 has a sidewall thickness T5 that is approximately equal to IC die thickness T2.

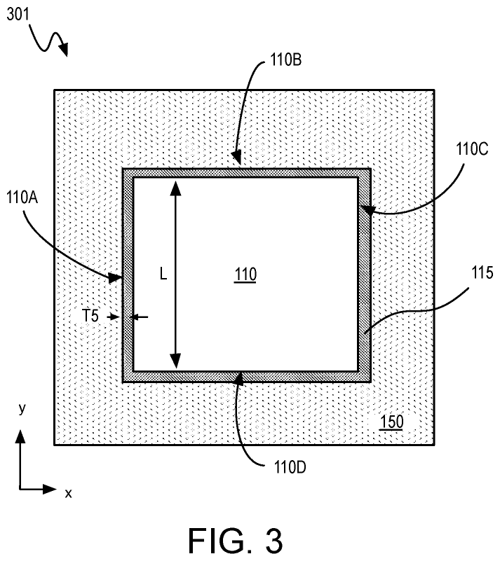

FIG. 3 illustrates a plan view of a die package 301 including heat spreading material 115, in accordance with some embodiments. Die package 301 represents a plan view applicable to any of die packages 101-105, and 201-203. In accordance with some CSP embodiments, the area or footprint of package material 150 is not significantly more than 1.2 times the area of IC die 110. In some such embodiments, where IC die has an area of no more than 25 mm², die edge length L may vary from 1-5 mm. Thermal conduction enhancement along the die edge lengths L may therefore significantly reduce the onset of thermal hot spots within IC die 110. As shown in FIG. 3, heat spreading material 115 forms a perimeter surrounding IC die edges 110A, 110B, 110C and 110D. Heat spreading material 115 is in contact with the IC die edges over their entire edge length L. In the illustrated example, heat spreading material 115 has substantially the same sidewall thickness T5 over each die edge 110A-110D.

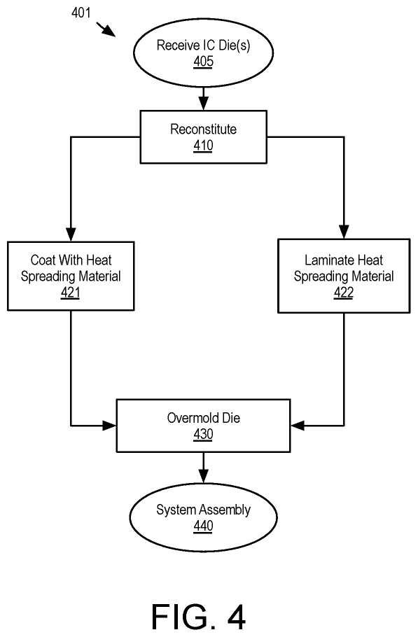

FIG. 4 illustrates a flow diagram of methods 401 for packaging an IC die that is at least partially covered with a heat spreading material comprising crystalline carbon, in accordance with some embodiments. Methods 401 may be employed to generate any of the IC packages 101-105 or 201-203, for example. Methods 401 begin at block 405 where IC die to be packaged are received. The IC die may be received from an IC chip or wafer manufacturer, for example. The IC die received may have been singulated and electrically tested, for example according to any suitable die prep and e-test process. Methods 401 continue at block 410 where multiple IC die are reconstituted onto a suitable carrier. In some exemplary embodiments, the reconstitution comprises coupling an active (front) surface of an IC die facing the carrier with one or more inactive surfaces of the IC die exposed.

The heat spreading material is then applied to the exposed inactive surfaces of the IC die. In some embodiments methods 401 continue to block 421 where the heat spreading material is applied as a coating over the exposed IC die surfaces. For such embodiments, deposition of the heat spreading material at block 421 may be by any technique known to be suitable for the material, such as, but not limited to liquid phase deposition (e.g., jet printing or spraying) techniques, solid phase deposition techniques (e.g., sputtering), or vapor phase deposition techniques (e.g., chemical vapor deposition), or gas phase deposition techniques (e.g., atomic layer deposition). In some embodiments, substantially pure graphene is deposited to a material thickness of 200 nm-1 μm. As noted above, such a material may have a thermal conductivity greater than 2500 W/mK. In some other examples, a liquid adhesive material (e.g., ink) comprising suspended (nano)particles of graphene is sprayed onto the exposed die surfaces. Any jetting process known to be suitable for spraying such a liquid may be employed. In some such embodiments, a graphene composite is spray deposited to a material thickness of 1-5 μm.

In other embodiments, methods 401 proceed from block 410 to block 422 where the heat spreading material is a preform (i.e., dry film), and a fan out-type of packaging process is employed. For example, where the heat spreading material comprises a graphite sheet, the graphite may be applied to the exposed surface of the IC die with any suitable lamination process. In some embodiments, the graphite or graphene impregnated preform has a thickness of 10-50 μm.

With the heat spreading material now on surfaces of the IC die, for example as applied to the die during a die prep stage, or as applied to the die during upstream wafer-level packaging, the IC die may be coupled to one or more metal redistribution layers. In some embodiments, the RDL is within a substrate, interposer or other package material to which the IC die may be attached with any die attach technique known in the art. In some examples, a flip chip process is employed where solder features are reflowed to couple the IC die to the package RDL. In some alternative fan out embodiments, a carrier may be removed from the IC die with the benefit of mechanical support from the heat spreading material. Any suitable fan out metallization and dielectric formation techniques may then be employed to complete electrical connections to the IC die. For example, a bumpless build-up process may be performed to couple the IC die to package RDL.

Methods 401 continue at block 430, where a package material is formed over the IC die and over any heat spreading material in contact with IC die surfaces. In some embodiments, an epoxy resin is applied with a molding process to encapsulate the IC die. The mold material may be applied over only a top surface of the package RDL, or may be applied to fully encapsulate sidewalls of the package RDL. Upon curing, the overmold or EDM package is ready for any suitable system level assembly at block 440.

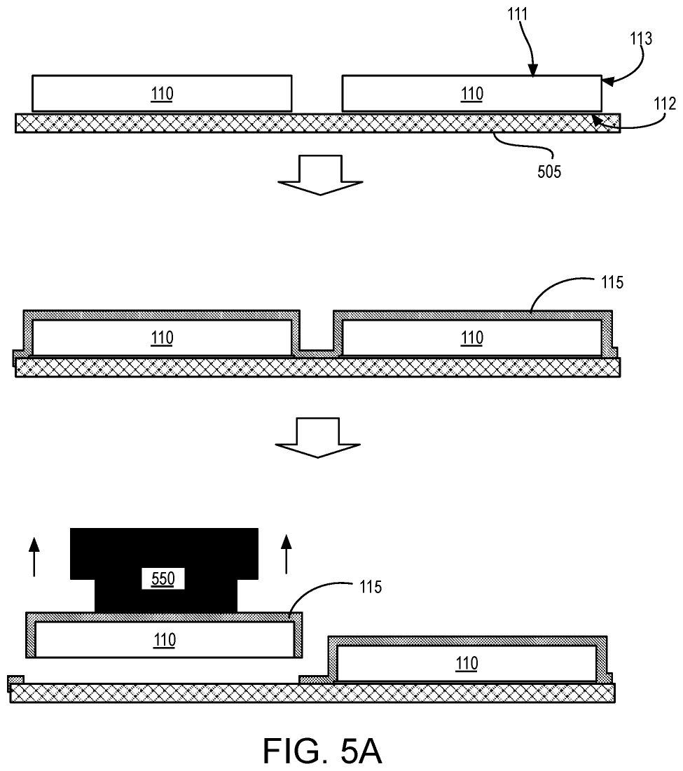

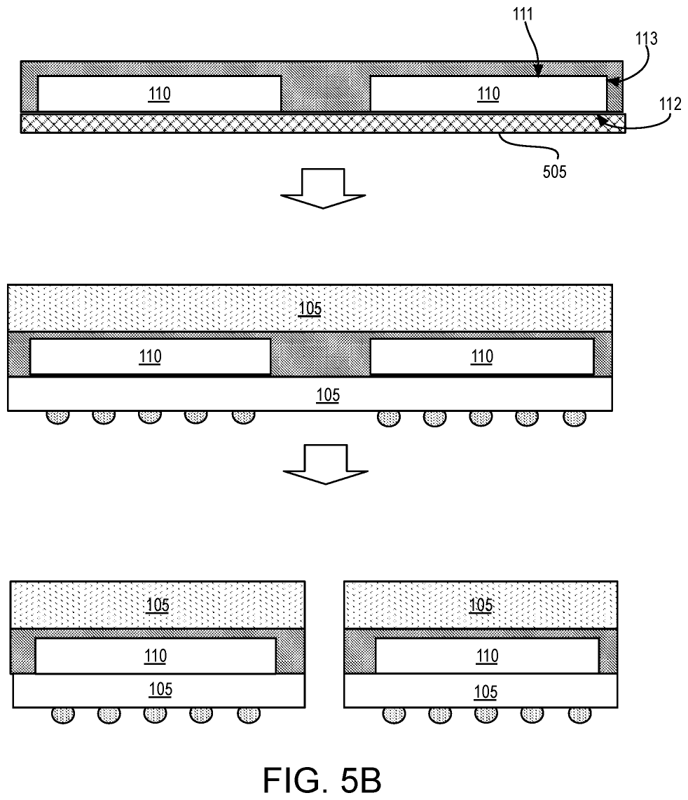

FIG. 5A illustrates selected operations in processing an IC die and IC package to include a heat spreading material comprising crystalline carbon, in accordance with some spray coating embodiments of methods 401 (FIG. 4). In FIG. 5A, two IC die 110 are shown on a carrier or tape 505 with the active surface (e.g., front side die surface 112) facing carrier 505. Heat spreading material 115 is then applied over all inactive surfaces (e.g., back side die surface 111 and die sidewall 113), for example with a spray coating process or any other technique known to be suitable for depositing graphene. IC die 110 are then removed from carrier 505, for example with a pick-and-place machine 550, which may then perform a flip-chip solder attachment to a package substrate (not depicted) followed by an epoxy overmold.

FIG. 5B illustrates selected operations in processing an IC die and IC package to include a heat spreading material comprising crystalline carbon, in accordance with some lamination embodiments of methods 401 (FIG. 4). In FIG. 5B, two IC die 110 are shown on a carrier or tape 505 with the active surface (e.g., front side surface 112) facing carrier 505. Heat spreading material 115 is then applied over all inactive surfaces (e.g., back side surface 111 and sidewall 113), for example with a dry film lamination process. One or more additional package materials 105 may further be applied over heat spreading material 115. Carrier 505 may then be removed and package material 105 comprising metal RDL is then formed, for example according to any known fan out technique. Individual IC packages are then generated from a singulation process (e.g., laser ablation, saw, etc.).

Notably, the die-level techniques described above provide within package heat spreading, which may be combined with system level thermal solutions, and can be used to dissipate heat away from the package, for example improving burst time parameters of a device. The integration of crystalline carbon-based materials at package level may suffer less from thermal contact resistance components relative to external thermal management approaches. For an overmolded IC package, the impact of adding an exemplary graphite coating at the die level can be modeled by considering a 5 μm graphite coating around the die with an in-plane thermal conductivity of ˜1000 W/mK and 3.4 W/mK through plane thermal conductivity. Assuming a passive heat sink is over a top of the package in a system enclosure that provides a cabinet for natural convection the graphite coating provides around a 25% improvement in the burst time for the ideal case of neglible contact resistance between the graphite coating and the IC die surface.

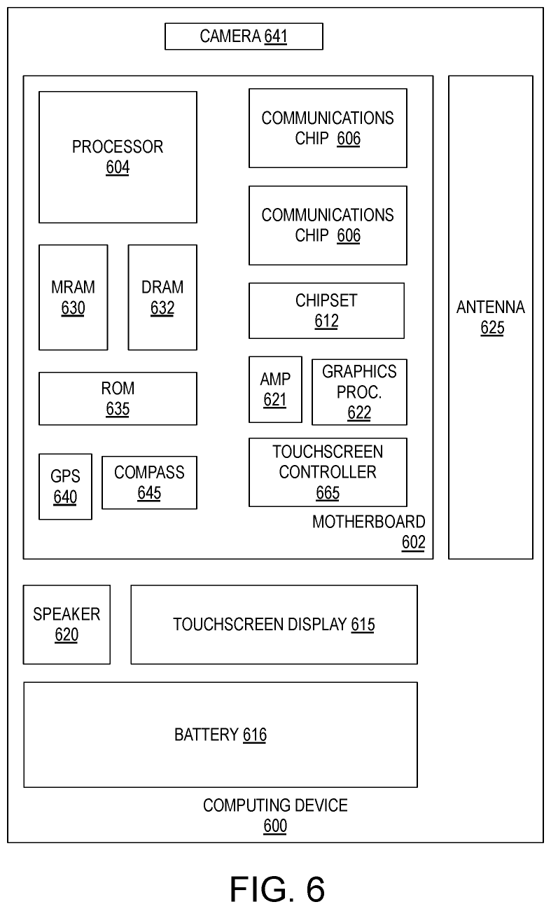

FIG. 6 is a functional block diagram of an electronic computing device 600, in accordance with an embodiment of the present invention. Device 600 further includes a motherboard 602 hosting a number of components, such as, but not limited to, a processor 604 (e.g., an applications processor). Processor 604 may be physically and/or electrically coupled to motherboard 602. In some examples, processor 604 includes an integrated circuit die packaged with a heat spreading material comprising crystalline carbon, which may be further bonded to an IHS. In general, the term “processor” or “microprocessor” may refer to any device or portion of a device that processes electronic data from registers and/or memory to transform that electronic data into other electronic data that may be further stored in registers and/or memory.

In various examples, one or more communication chips 606 may also be physically and/or electrically coupled to the motherboard 602. In further implementations, communication chips 606 may be part of processor 604. Depending on its applications, computing device 600 may include other components that may or may not be physically and electrically coupled to motherboard 602. These other components include, but are not limited to, volatile memory (e.g., DRAM 632), non-volatile memory (e.g., ROM 635), flash memory (e.g., NAND or NOR), magnetic memory (MRAM 630), a graphics processor 622, a digital signal processor, a crypto processor, a chipset 612, an antenna 625, touchscreen display 615, touchscreen controller 665, battery 616, audio codec, video codec, power amplifier 621, global positioning system (GPS) device 640, compass 645, accelerometer, gyroscope, speaker 620, camera 641, and mass storage device (such as hard disk drive, solid-state drive (SSD), compact disk (CD), digital versatile disk (DVD), and so forth), or the like. In some exemplary embodiments, at least one of the functional block noted above comprise an IC package with a heat spreading material comprising crystalline carbon, for example as described elsewhere herein.

Communication chips 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 606 may implement any of a number of wireless standards or protocols, including but not limited to those described elsewhere herein. As discussed, computing device 600 may include a plurality of communication chips 606. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

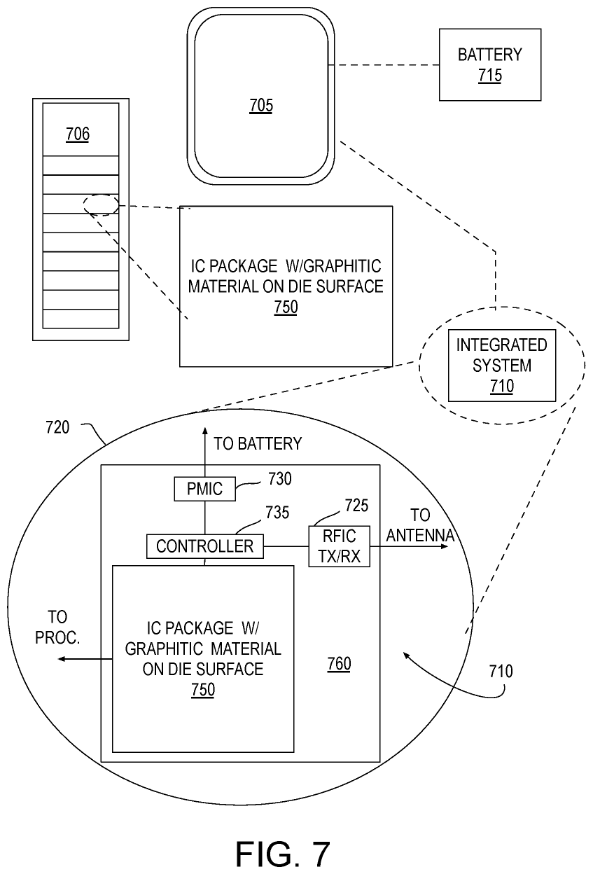

FIG. 7 illustrates a mobile computing platform and a data server machine employing a IC package with a heat spreading material comprising crystalline carbon, for example as described elsewhere herein. Computing device 600 may be found inside platform 705 or server machine 706, for example. The server machine 706 may be any commercial server, for example including any number of high-performance computing platforms disposed within a rack and networked together for electronic data processing, which in the exemplary embodiment includes a packaged SoC 750 that further includes a heat spreading material comprising crystalline carbon. The mobile computing platform 705 may be any portable device configured for each of electronic data display, electronic data processing, wireless electronic data transmission, or the like. For example, the mobile computing platform 705 may be any of a tablet, a smart phone, laptop computer, etc., and may include a display screen (e.g., a capacitive, inductive, resistive, or optical touchscreen), a chip-level or package-level integrated system 710, and a battery 715.

Whether disposed within the integrated system 710 illustrated in the expanded view 720, or as a stand-alone chip within the server machine 706, IC package 750 may include a heat spreading material comprising crystalline carbon. IC package 750 may be further coupled to a board, a substrate, or an interposer 760 along with, one or more of a power management integrated circuit (PMIC) 730, RF (wireless) integrated circuit (RFIC) 725 including a wideband RF (wireless) transmitter and/or receiver (TX/RX) (e.g., including a digital baseband and an analog front end module further comprises a power amplifier on a transmit path and a low noise amplifier on a receive path), and a controller 735.

Functionally, PMIC 730 may perform battery power regulation, DC-to-DC conversion, etc., and so has an input coupled to battery 715 and with an output providing a current supply to other functional modules. As further illustrated, in the exemplary embodiment, RFIC 725 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example the above embodiments may include specific combinations of features as further provided below.

In first examples, an integrated circuit package comprises a die comprising an integrated circuit, a first dielectric material adjacent to a surface of the die, and a second dielectric material between the surface of the die and the first dielectric material, the second dielectric material comprising crystalline carbon.

In second examples, for any of the first examples the surface is an edge sidewall of the die, and the second dielectric material comprises graphene or graphite.

In third examples, for any of the second examples the second dielectric material has anisotropic thermal conductivity with a highest thermal conductivity in a plane non-orthogonal to the surface of the die.

In fourth examples, for any of the first through third examples the first dielectric material has a thermal conductivity less than 4 W/mK, and the second dielectric material has a thermal conductivity of at least 400 W/mK.

In fifth examples, for any of the first through the fourth examples the second dielectric material comprises a matrix material, and the crystalline carbon is in the matrix material.

In sixth examples, for any of the first through the fifth examples, the first dielectric material and the second dielectric both comprise at least one of an epoxy or silicone.

In seventh examples, for any of the first through the sixth examples, the second dielectric material is in contact with the surface of the die, and the first dielectric material is in contact with the second dielectric material.

In eighth examples, for any of the first through the seventh examples a first surface of the die having an area of no more than 25 mm² is interconnected by a plurality of solder features to a package substrate. The die has four edge surfaces intersecting the first and second surfaces of the die, each of the four edge surfaces associated with a sidewall length and a sidewall height. The second dielectric material is in contact with the four edge surfaces over substantially the entire sidewall length and sidewall height, and the first dielectric material forms a perimeter around the four edge surfaces.

In ninth examples, for any of the eighth examples, the second dielectric material is in contact with a second surface of the die, opposite the first surface, and the second dielectric material is absent from the first surface of the die.

In tenth examples, for any of the ninth examples the first dielectric material is over the second surface of the die, and the second dielectric material is between the first dielectric material and the second surface of the die

In eleventh examples, for any of the first through tenth examples, the second dielectric material thickness, in a direction normal from the surface of the die, is no more than 3 μm, or is at least 10 μm.

In twelfth examples, for any of the eleventh examples, a height of the die surface is less than 200 μm, and the second dielectric material thickness is at least 20% of the height of the die surface.

In thirteenth examples, a computer system comprises a power supply, a system component comprising interconnect circuitry, and one or more integrated circuit packages coupled to the system component. At least one of the integrated circuit packages further comprises an IC die, a first dielectric material surrounding a perimeter of the IC die, and a second dielectric material between a surface of the IC die and the first dielectric material, the second dielectric material comprising crystalline carbon.

In fourteenth examples, for any of the thirteenth examples the at least one of the integrated circuit packages further comprises a package substrate, a center portion of the package substrate coupled to a first surface of the IC die through a plurality of solder features. The second dielectric material is over a perimeter portion of the package substrate, the second dielectric material in contact with a plurality of edge sidewalls of the IC die, and the first dielectric material is in contact with the second dielectric material.

In fifteenth examples, for any of the thirteenth through fourteenth examples, the first surface of the IC die has an area of no more than 25 mm², the edge sidewalls have a sidewall height that is less than 200 μm, the second dielectric material has a thickness, in a direction normal to the edge sidewalls, of either less than 1% of the sidewall height, or more than 10% of the sidewall height.

In sixteenth examples, a method of assembling an integrated circuit (IC) package comprises receiving an IC die, applying a first dielectric material comprising crystalline carbon over at least one surface of the IC die, and applying a second dielectric material around the IC die and the first dielectric material.

In seventeenth examples, for any of the sixteenth examples the method further comprises attaching a first surface of the IC die to a package substrate with a plurality of solder features. The first dielectric material is applied prior to attaching the first surface of the IC die to the package substrate. The second dielectric material is applied after attaching the first surface of the IC die to the package substrate.

In eighteenth examples, for any of the seventeenth examples applying the second dielectric material comprises molding an epoxy, having a thermal conductivity at least two orders of magnitude smaller than that of the first dielectric material, around a perimeter of the first dielectric material.

In nineteenth examples, for any of the sixteenth through eighteenth examples applying the first dielectric material comprises depositing a coating comprising the crystalline carbon over the IC die, or laminating a dry film comprising the crystalline carbon over the IC die.

In twentieth examples for any of the nineteenth examples applying the first dielectric material comprises depositing the coating or dry film in contact with an edge sidewall of the IC die.

What is claimed is:

1. An integrated circuit package, comprising:
a die comprising an integrated circuit;
a first dielectric material adjacent to a surface of the die; and
a second dielectric material between the surface of the die and the first dielectric material, the second dielectric material comprising crystalline carbon.

2. The integrated circuit package of claim 1, wherein:
the surface is an edge sidewall of the die; and
the second dielectric material comprises graphene or graphite.

3. The integrated circuit package of claim 2, wherein the second dielectric material has anisotropic thermal conductivity with a highest thermal conductivity in a plane non-orthogonal to the surface of the die.

4. The integrated circuit package of claim 1, wherein:
the first dielectric material has a thermal conductivity less than 4 W/mK; and
the second dielectric material has a thermal conductivity of at least 400 W/mK.

5. The integrated circuit package of claim 1, wherein the second dielectric material comprises a matrix material, and the crystalline carbon is in the matrix material.

6. The integrated circuit package of claim 5, wherein the first dielectric material and the second dielectric material both comprise at least one of an epoxy or silicone.

7. The integrated circuit package of claim 1, wherein the second dielectric material is in contact with the surface of the die, and the first dielectric material is in contact with the second dielectric material.

8. The integrated circuit package of claim 1, wherein:
a first surface of the die having an area of no more than 25 mm² is interconnected by a plurality of solder features to a package substrate;
the die has four edge surfaces intersecting the first and second surfaces of the die, each of the four edge surfaces associated with a sidewall length and a sidewall height;
the second dielectric material is in contact with the four edge surfaces over substantially the entire sidewall length and sidewall height; and
the first dielectric material forms a perimeter around the four edge surfaces.

9. The integrated circuit package of claim 8, wherein:
the second dielectric material is in contact with a second surface of the die, opposite the first surface; and
the second dielectric material is absent from the first surface of the die.

10. The integrated circuit package of claim 9, wherein the first dielectric material is over the second surface of the die, and the second dielectric material is between the first dielectric material and the second surface of the die.

11. The integrated circuit package of claim 1, wherein the second dielectric material thickness, in a direction normal from the surface of the die, is no more than 3 μm, or is at least 10 μm.

12. The integrated circuit package of claim 11, wherein a height of the surface of the die is less than 200 μm, and the second dielectric material thickness is at least 20% of the height of the surface of the die.

13. A computer system, comprising:
a power supply;
a system component comprising interconnect circuitry; and
one or more integrated circuit packages coupled to the system component, wherein at least one of the integrated circuit packages further comprises:
an IC die;
a first dielectric material surrounding a perimeter of the IC die; and
a second dielectric material between a surface of the IC die and the first dielectric material, the second dielectric material comprising crystalline carbon.

14. The computer system of claim 13, wherein:
the at least one of the integrated circuit packages further comprises a package substrate, a center portion of the package substrate coupled to a first surface of the IC die through a plurality of solder features;
the second dielectric material is over a perimeter portion of the package substrate, the second dielectric material in contact with a plurality of edge sidewalls of the IC die; and
the first dielectric material is in contact with the second dielectric material.

15. The computer system of claim 14, wherein:
the first surface of the IC die has an area of no more than 25 mm²;
the edge sidewalls have a sidewall height that is less than 200 μm;
the second dielectric material has a thickness, in a direction normal to the edge sidewalls, of either less than 1% of the sidewall height, or more than 10% of the sidewall height.

16. A method of assembling an integrated circuit (IC) package, the method comprising:
receiving an IC die;
applying a first dielectric material comprising crystalline carbon over at least one surface of the IC die; and
applying a second dielectric material around the IC die and the first dielectric material.

17. The method of claim 16, further comprising attaching a first surface of the IC die to a package substrate with a plurality of solder features, wherein the first dielectric material is applied prior to attaching the first surface of the IC die to the package substrate, and wherein the second dielectric material is applied after attaching the first surface of the IC die to the package substrate.

18. The method of claim 17, wherein applying the second dielectric material comprises molding an epoxy, having a thermal conductivity at least two orders of magnitude smaller than that of the first dielectric material, around a perimeter of the first dielectric material.

19. The method of claim 16, wherein applying the first dielectric material comprises depositing a coating comprising the crystalline carbon over the IC die, or laminating a dry film comprising the crystalline carbon over the IC die.

20. The method of claim 19, wherein applying the first dielectric material comprises depositing the coating or dry film in contact with an edge sidewall of the IC die.
